(19) United States
(12) Patent Application Publication
(10) Pub. No.: US 2010/0134973 A1
(43) Pub. Date: Jun. 3, 2010

(54) BENDABLE MECHANISM AND BENDABLE SLIDING OPENING TYPE APPARATUS

(76) Inventor: Han Sang Lee, Seoul (KR)

Correspondence Address: OSTROLENK FABER GERB & SOFFEN, 1180 AVENUE OF THE AMERICAS, NEW YORK, NY, 100368403, US

(21) Appl. No.: 12/597,595

(22) PCT Filed: May 7, 2008
(86) PCT No.: PCT/KR08/02566

§ 371 Date: Oct. 26, 2009

(30) Foreign Application Priority Data
May 9, 2007 (KR) 10-2007-0045167

(51) Int. Cl. H05K 7/00; H05K 5/00; E05D 11/00

(52) U.S. Cl. 361/679.56; 16/223

(57) ABSTRACT

A bendable apparatus, which is able to change its state between a straightened state and a bent state using an external force, is disclosed. This bendable apparatus includes a top bracket and a bottom bracket which is rotatably axle-joined with the top bracket. Also, the bendable apparatus includes a swing link, which is rotatably axle-joined to the top bracket, concurrently engages with a portion of the bottom bracket, and makes the bottom bracket rotate itself about the top bracket by an external force applied to a swing link protrusion and by a predetermined angle about an axle with which the bottom bracket is joined with the top bracket. When the external force is applied to an opposite direction, the bendable apparatus goes back to the straightened state. If this bendable apparatus is applied to a mobile phone of a sliding opening type, a portion with a microphone can be bent by a predetermined angle when the mobile phone is opened.

### TECHNICAL FIELD

The invention relates to a sliding apparatus, and more specifically, to a bendable sliding apparatus that can be applied to mobile devices including a cellular phone, a PDA, and a mobile PC, in which a moving member that is slidably combined to a base member may be bent by a predetermined angle when opened.

### BACKGROUND ART

For example, categorizing mobile phones according to opening types, the folder type and the slide type have been provided widely. In a folder type mobile phone, a folder member and a base member are joined together enabling the mobile phone to fold, and they open in a bent state with about 140-160 degrees, but not in a straight line. In such a bent state, a microphone at a bottom portion of the base member and a speaker at a top portion of the folder member are located close to the mouth and the ear of a user, respectively, in a natural fashion.

Contrastingly, a traditional slide type mobile phone includes a base member and a moving member which is combined face-to-face with the base member and guided by the base member to be slidable, in which, when sliding the moving member upward, it slides along a straight line elongating the length of the mobile phone, such that the base member and the moving member form 180 degrees. Thus, in the slide type mobile phone, the microphone and the speaker get to be located less closer to the mouth and the ear of the user. That is, if the speaker comes closer to the ear of the user in the slide type mobile phone, the microphone gets to be away farther from the mouth of the user comparing to the folder type mobile phone. Therefore, the user needs to talk louder to the slide type mobile phone.

On the other hand, recently the mobile phone is frequently used to display a TV broadcast or video clips. In order to watch in a landscape format without changing the angle of the screen, the mobile phone must stand on its side. For example, to watch on a table or desk for a long time, sometimes it is convenient to put the mobile phone on the top of the table or desk sideways and watch. With the traditional slide type mobile phone, since the base member and the moving member form 180 degrees, standing the mobile phone on its side is not impossible but it is so unstable that it is easily toppled down even to a little jerking. In contrast, the folder type mobile phone stands on its side quite stably thanks to its bending of the base member and the moving member.

Many users prefer the slide type mobile phone to the folder type mobile phone for easy opening and closing, but it needs to be improved in its lack of the merits of the folder type mobile phone, the microphone/speaker's getting closer to the user's mount and ear and standing on its side stably. This merits needs to be considered in other devices employing the sliding opening mechanism.

### DISCLOSURE OF INVENTION

### Technical Problem

One objective of the invention is to provide a bendable apparatus (element), which has a mechanism of being closed on hold and open on release and, when applied to a device adopting a sliding opening mechanism, if a moving member is guided on the a base member and slides to open, the moving member is bent by some angle, and if the moving member slides to an opposite direction, the moving member is straightened.

Other objective of the invention is to provide a slide type mobile phone having the bendable apparatus of the above, in which a portion of the moving member is bent about the base member when opening the moving member, and the entire moving member is straightened in a line and aligned with the base member when closing the moving member.

### Technical Solution

According to an aspect of the invention to accomplish the above objectives, a bendable apparatus is provided, which comprises: a top bracket; a bottom bracket which is rotatably axle-joined with the top bracket; and a swing link which is rotatably axle-joined to the top bracket, concurrently engages with a portion of the bottom bracket, and makes the bottom bracket rotate about the top bracket by an external force applied to a swing link protrusion and by a predetermined angle about an axle with which the bottom bracket is joined with the top bracket is being rotated itself about the top bracket by an external force applied to a swing link protrusion, and makes the bottom bracket rotate by a predetermined angle about an axle which is joined with the top bracket.

The bendable apparatus may further comprise a spring member which is disposed between the top bracket and the bottom bracket and applies a pushing force to the two brackets in an opposite direction. Also, the bendable apparatus may further comprise an engaging axle inserted into through-holes provided in the two brackets to join the bottom bracket with the top bracket.

For an axle-joining between the top bracket and the bottom bracket, an entering hole is formed in one of the top bracket and the bottom bracket, and an axle is formed in the other of the top bracket and the bottom bracket at a position corresponding to the entering hole. In addition, the top bracket is axle-joined with the bottom bracket by the axle's inserting into the entering hole.

For the bottom bracket's rotation, the swing link engages the bottom bracket by the axle of the bottom bracket inserting into a swing link groove formed in a body of the swing link. By these engagements, the axle of the bottom bracket is forcibly guided to the swing link groove rotating with the body of the swing link, and then the bottom bracket rotates by the predetermined angle. Here, the rotating angle of the bottom bracket may be limited by a length of the swing link groove or a structure, in which when the bottom bracket rotates by a predetermined angle, the bottom bracket touchesis blocked by a part of the top bracket and cannot rotate any further.

The bendable apparatus may keep either a closed state in which the bottom bracket is aligned with the top bracket in a straight line without a gap, or a bent state in which the bottom bracket is opened against the top bracket by the predetermined angle, according to the rotation angle of the swing link. And, the closed state and the bent state may be turned into each other in either direction. As long as the swing link does not rotate in the closed state and the bent state, the bottom bracket is not able to rotate, being left in a gapless state.

To facilitate assembling of the bendable apparatus, two bendable apparatuses can be combined into a structure using a link member having a shape of a bar. In this case, the link member may comprise either a first link member for connecting first and second top brackets of the two bendable apparatuses, or a second link member for connecting first and second bottom brackets of the two bendable apparatuses.

For the state change between the closed state and the bent state, the bendable apparatus must be subject to an external force. The external force needs to be applied to the swing link. For receiving the external force, the swing link comprises a protrusion extended and exposed externally from a side of the body to an outside of the top bracket and the bottom bracket, and has a structure in which the external force is applied through the protrusion.

The bendable apparatus may be applied to other devices as a part for supporting a bending motion. In such a case, in order to be combined to the devices, each of the top bracket and the bottom bracket may be provided with a fastening-hole for connecting with other objects through screws.

On the other hand, the bendable apparatus may be changed in other embodiments. For an example, a bendable apparatus may be provided, comprising: a top bracket; a bottom bracket which is rotatably axle-joined with the top bracket; a swing link which is rotatably axle-joined to the top bracket and includes a swing link protrusion exposed externally; and a link which is disposed between the bottom bracket and the swing link and is rotatably axle-joined to the bottom bracket and the swing link at both ends, wherein the swing link rotates about the top bracket by the external force applied to itself through the swing link protrusion and pulling up the link, and wherein the bottom bracket is led by the link to rotate about the top bracket by a predetermined angle.

The bendable apparatus may comprise a pair of each of the top brackets, the bottom brackets, the swing links, and the links, and may have a structure in which the said pair of bottom brackets may be connected to each other into one body through a bar-shaped link member, which results in a structure that each of the bendable apparatuses is provided at both ends of the link member.

For receiving the external force, the swing link in the bendable apparatus may comprise a protrusion extended from a side of the body of the swing link externally to the top bracket and the bottom bracket.

In other embodiments, a bendable apparatus is provided, comprising: a bottom bracket portion comprising a bar-shaped body, an engaging axle extended at both sides of the a bar-shaped body and a pair of bottom brackets fixed integrally in a vicinity of each of both left and right edges of the body, wherein each of the bottom brackets includes a base portion, fixed to the body, having a top surface fixed to the body and tilted with an angle to the bottom surface of the body and a protrusion portion erected perpendicularly downward from an outer edge of the base portion, and a top bracket portion comprising a pair of top brackets, each of which being rotatably engaged to the engaging axle in both side of the body, wherein the top bracket comprises an engaging portion which faces a side of the body and axle-joined to the engaging axle and a rotation-limiting portion which faces the top surface of the base portion of the bottom bracket with an angle and limits the rotating angle of the bottom bracket, wherein the bottom bracket rotates by a predetermined angle about the top bracket when an external force is applied to the protrusion portion.

On the other hand, the bendable apparatus may be applied to electronic devices, employing a sliding opening type, including, for example, a cellular phone, a PDA, a smart phone, and a notebook computer in order to obtain bendable sliding opening type devices. The bendable sliding opening type devices comprises: the bendable apparatus disclosed in the above; a base portion provided with a guide groove extending in a direction of length thereof, a bending-catching groove having a depth deeper than the guide groove provided at an end of bottom of the guide groove, and a bottom portion includes a tilted surface; and top and bottom moving portions fixed respectively to the top bracket and the bottom bracket and moving integrally, wherein the moving portion faces and engages the base portion so as to allow a sliding motion, wherein the bottom moving portion is straightened in a straight line against the top moving portion so as to keep a closed state (straightened state) when the swing link protrusion of the bendable apparatus is in the guide groove, wherein after the bendable apparatus slides and moves downward under an external force pulling down the moving portion and then the swing link protrusion enters into the bending-catching groove it get caught therein and proceed no more and the swing link rotates in a first direction such that the bottom bracket is forced to rotate toward the tilted surface against the top bracket by an angle, and thereby the bottom moving portion moving together with the bottom bracket goes over to a bent state.

In such a sliding opening type electronic devices, in a process that the swing link protrusion escapes the bending-catching groove with an external force which pushes upward and gets on the guide groove, the swing link is forced to rotate by an angle in a direction opposite to the first direction by the applied force, and thereby the bottom moving portion moving together with the bottom bracket goes back to the closed state (straightened state).

A guide rail which runs along the guide groove may be provided on both sides of the base portion and fixed on sliders fixed on both sides of the bottom surface of the top moving portion, and the sliders are slidably engaged to the guide rails.

Also, in order to support more smooth sliding motion, the electronic devices may further comprise a torsion spring for providing a force to pull down or push up to the ends, in which one arm is engaged to the bottom surface of the top moving portion and other arm is engaged to the top surface of the base portion, when the moving portion performs a sliding motion upward or downward.

In the electronic devices, the guide groove and the bending-catching groove may be provided so as to run together with side edges on both sides of the base portion.

In manufacturing the electronic device, in order to reduce assembling steps, the top bracket and the bottom bracket may be designed to be integrated with the top moving portion and the bottom moving portion respectively such that it is going to be enough to assemble the swing link with the top bracket and the bottom bracket.

If such a bendable apparatus is applied to a sliding opening type cellular phone, a representative device having a sliding opening, the moving portion is bent by some angle when opened so as to have the microphone and the speaker of the cellular phone come closer to the mouth and the ear of a user as in the case of a folder type cellular phone, and also enables the phone to stand on its side for watching a DMB conveniently.

If a keypad and a screen are disposed respectively in a circuit board member and a sliding member of a sliding opening type electronic device, the screen may be disposed conveniently in a tilted upright position with the keypad is opened.

### Advantageous Effects

The present invention can be applied to a sliding type open-and-close cellular phone, and enables the phone bent by an angle when the phone is being opened as in a folder type cellular phone. Therefore, the advantage of a sliding type, easy open and close, and the advantage of a folder type, disposing microphone and speaker close to a user's mouth and ear, can be combined. Also, the cellular phone stands on its side stably. This feature frees the user from holding the 90 degree rotated cellular phone for a long time while watching TV or video clips.

Furthermore, the present invention can be applied to a small-sized PDA or notebook computer. The substrate portion can rest on a floor with the screen raised by an angle, making it easy to use keyboard.

### BRIEF DESCRIPTION OF THE DRAWINGS

FIGS. 1-3 show a bendable sliding type cellular phone (100),

where FIGS. 1(a)-(c) show appearance of the assembled cellular phone (100) in a closed state, an opened state, and a bent state, FIGS. 2(a)-(c) show cross-section side views corresponding to FIG. 1, and FIG. 3 shows an exploded perspective view of the cellular phone (100).

FIGS. 4 and 5 show an exploded perspective view and an assembled view of a bendable apparatus (140) according to a first embodiment of the invention.

FIG. 6 shows a cross-sectional perspective view along the line A-A of FIG. 1.

*FIG. 7(a) shows a perspective view illustrating the bendable sliding type cellular phone (100) of FIG. 1 in a closed state with the top moving portion (120) and the bottom moving portion (130) removed, and FIG. 7(b) shows an exploded perspective view of the top moving portion (120) and the bottom moving portion (130) in an opened state.

FIG. 8(a) shows a perspective view illustrating the bendable sliding type cellular phone (100) of FIG. 1 in a closed state with the base portion (110) removed, and FIG. 8(b) shows a perspective view illustrating an opened state with the bottom moving portion (130) bent.

FIGS. 9(a)-(c) show cross-sectional views along the lines B-B, C-C, and D-D.

FIG. 10 shows an exploded perspective view of a bendable apparatus (240) according to a second embodiment of the invention.

FIGS. 11(a)-(b) show assembled views of the bendable apparatus (240) of FIG. 10 in a closed state and a bent state.

FIG. 12 shows an exploded perspective view of a bendable apparatus (340) according to a second embodiment of the invention.

FIGS. 13(a)-(b) show assembled views of the bendable apparatus (340) of FIG. 12 in a closed state and a bent state.

FIGS. 14(a)-(c) show cross-sectional views of the bendable apparatus (340) of FIG. 12 installed on a sliding type cellular phone (100) along the lines B-B, C-C, and D-D of FIG. 1.

FIGS. 15(a)-(b) show an exploded perspective view and an assembled view of a bendable apparatus (440) according to a fourth embodiment of the invention.

FIGS. 16(a)-(b) show cross-sectional views of the bendable apparatus (440) of FIG. 15 installed on a sliding type cellular phone (100) along the lines B-B and D-D of FIG. 1.

FIGS. 17(a)-(b) show an exploded perspective view and an assembled view of a bendable apparatus (540) according to a fifth embodiment of the invention.

FIGS. 18(a)-(b) show an exploded perspective view and an assembled view of a bendable apparatus (640) according to a sixth embodiment of the invention.

FIGS. 19(a)-(b) show an exploded perspective view and an assembled view of a bendable apparatus (740) according to a seventh embodiment of the invention.

FIGS. 20(a)-(b) show an exploded perspective view and an assembled view of a bendable apparatus (840) according to an eighth embodiment of the invention.

FIG. 21 shows an exploded perspective view of a bendable apparatus (940) according to a ninth embodiment of the invention, FIG. 22(a)-(b) show a closed state and an opened state of the assembled apparatus, and FIGS. 23(a)-(b) show cross-sectional view illustrating the state transition between the closed state and the bent state of the bendable apparatus (940).

FIG. 24 shows an exploded perspective view of a bendable apparatus (1040) according to a tenth embodiment of the invention, FIG. 25(a)-(b) show a closed state and an opened state of the assembled apparatus, and FIGS. 26(a)-(b) show cross-sectional view illustrating the state transition between the closed state and the bent state of the bendable apparatus (1040).

FIG. 27 shows a base portion of a bendable sliding type cellular phone according to a modified embodiment.

### BEST MODE FOR CARRYING OUT THE INVENTION

### (1) First Embodiment

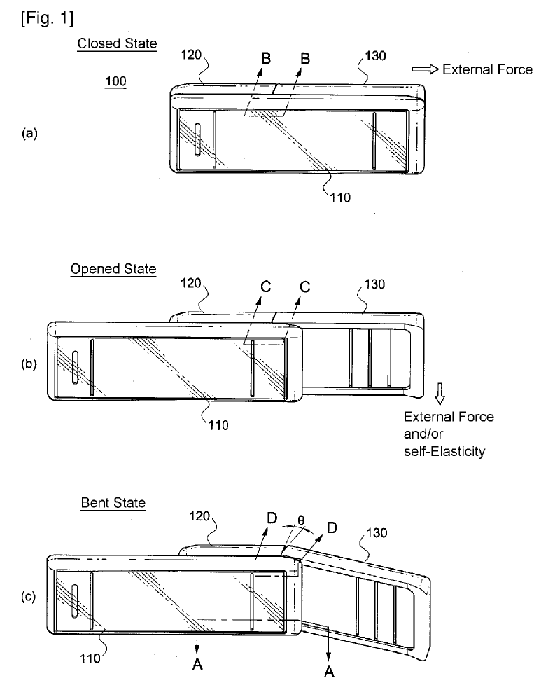

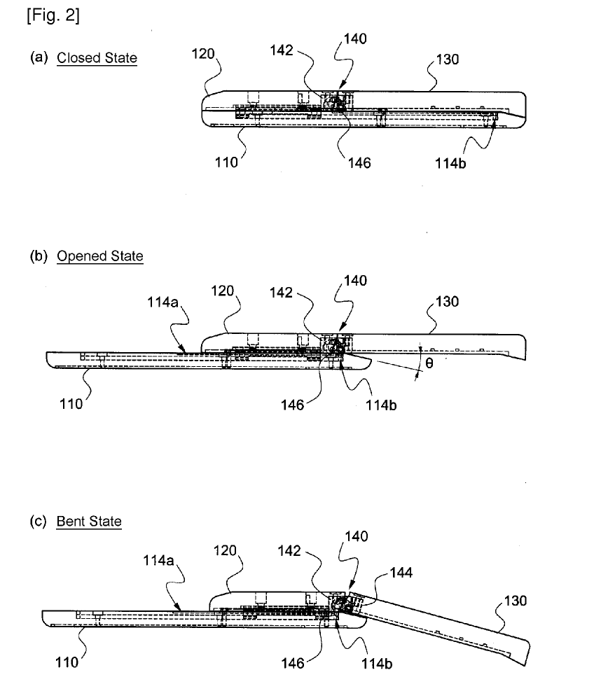

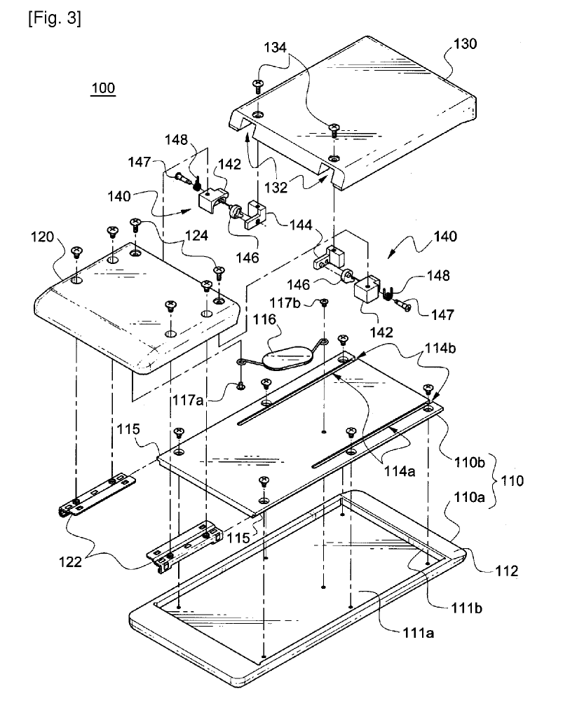

The invention is described more specifically referring to the figures. FIGS. 1 through 3 show a bendable sliding type cellular phone (100) according to an embodiment of the invention. FIG. 1(a)-(c) are perspective views illustrating a closed state, an opened state, and a bent state of the bendable sliding type cellular phone (100) respectively, FIG. 2(a)-(c) are side cross-sectional views corresponding to each state in FIG. 1, and FIG. 3 shows an exploded perspective view of the bendable sliding type cellular phone (100).

The cellular phone (100) comprises a base portion (110), and a top moving portion (120) and a bottom moving portion (130) that are slidably engaged with the base portion (110). For example, a speaker (not shown) is disposed at a topmost part of the base portion (110), a screen (not shown) below the speaker, a speaker (not shown) at a bottommost part of the bottom moving portion (130), and a keypad (not shown) above the speaker. The top moving portion (120) and the bottom moving portion (130) are connected to each other in a line as to move together. The cellular phone (100) goes through three state changes when opened or closed. When opening the cellular phone (100), the two moving portions (120, 130) push up the base portion (110) to the end such that starting a completely folded state (‘closed state’) against the base portion (110), it goes through a state in which the bottom moving portion (130) is about to bend by pulling down the two moving portions (120, 130) to the end (opened state) and a state in which the bottom moving portion (130) is bent by an angle (θ) from the opened state and then the top moving portion (120) and the bottom moving portion (130) is bent (‘bent state’) in order. When closing the cellular phone (100), it goes through the states in reverse order. To change the closed state to the opened state, the user must apply a force pulling down the moving portions (120, 130). The force for changing the opened state to the bent state is an elastic force provided by a bendable apparatus (140) described below and/or an external force exerted by the user.

The base portion (110) comprises a base body (110a) and a guide plate (110b). The base body (110a) forms a sink (111a) for accepting the guide plate (110b) in the perimeter of a top surface, and a tilted surface (112) is provided beyond a side wall at lower side (in a direction from the top moving portion (120) to the bottom moving portion (130)) of the sink (111a). Guide rails (115) are provided by forming a step along both sides of the guide plate (110b), and guide grooves (114a) having some length are formed slightly apart from the both sides. The guide grooves (114a) are formed deeper around a bottom surface of the guide plate (110b). When the guide plate (110b) is fixed to the base body (110a), for example, with screws, bending-catching grooves (114b) surrounded by a side wall close to the tilted surface (112) of the guide groove (114a), a side wall of the sink (111a), and a bottom wall are provided. The bending-catching groove (114b) is deeper than the guide groove (114a) viewing from the side, forming a two-step groove. A torsion spring (116) is provided between the base portion (110) and the top moving portion (120). An arm (117a) of the torsion spring (116) is fixed to the top moving portion (120), and the other arm (117b) is fixed to the base portion (110).

A slider (122) is fixed to the top moving portion (120) at its both sides of a bottom surface, for example, with screws, and the sliders (122) slidably engage the guide rails (115) provided on both sides of the guide plates (110b). Also, the top moving portion (120) is connected with the bottom moving portion (130) serially so as to move together in a sliding motion. The top moving portion (120) and the bottom moving portion (130) are connected to each other into one by the bendable apparatus (140). Installing grooves (126, 132) facing each other are provided on both sides of bottom portions of the top moving portion (120) and top portions of the bottom moving portions (130) respectively, and the bendable apparatus (140) is installed in a space formed by pairs of installing grooves (126, 132) on both sides.

The bendable apparatus (140) comprises a top bracket (142), a bottom bracket (144), an engaging axle (147) for axle-joining the two brackets, and a swing link (146) engaging the two brackets (142, 144) for guiding (forcing) the bending motion and the straightening motion. A torsion spring (148) may be further comprised, which is provided between the top bracket (142) and the bottom bracket (144) and applies force in a direction where the two brackets (144) are bent. The top bracket (142) and the bottom bracket (144) are fixed to the bottom portions of the top moving portion (120) and the top portions of the bottom moving portion (130) respectively with screws (124, 134). Once fixed, the bendable apparatus (140) is aligned on the guide groove (114a).

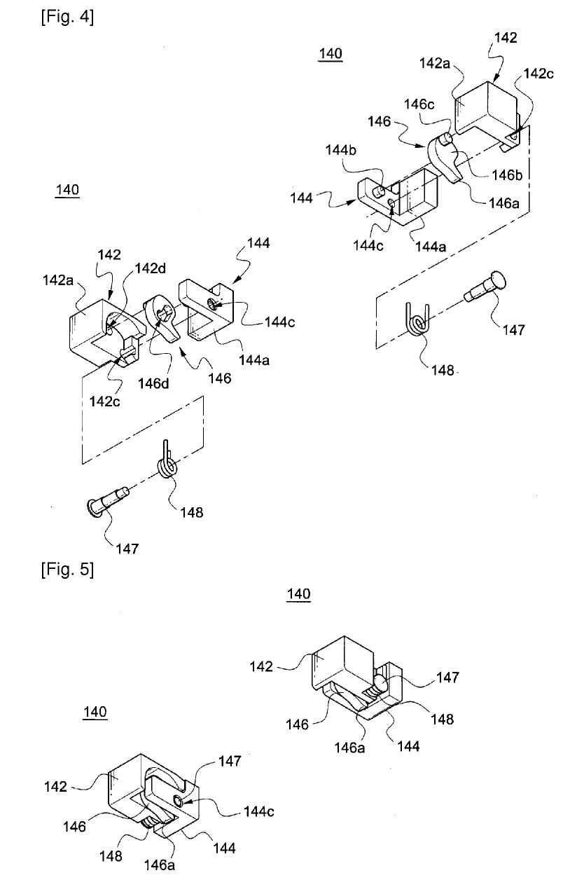

A bendable apparatus (140) according to the first embodiment is specified referring to FIGS. 4 and 5. The swing link (146) comprises a swing link protrusion (146a) extended outward from a side of the body (146b) having a shape of substantially flat elliptical column, a guide groove (146d) formed on one side of the body (146b), and a swing link axle (146c) extending perpendicularly from a perimeter on the other side (a position farthest from the swing link protrusion (146a)). The guide groove (146) penetrates a central portion of the body (146b), extends in a direction of length, and an end portion is slightly crooked. The top bracket (120) provides an accepting space on a side of a body (142a) having a substantially parallelepiped shape, in which the swing link (146) and a vertical portion of the bottom bracket body (144a) are received, in a bottom portion of which an entering groove (142d) into which the swing link axle (146c) is inserted and an entering hole (142c) into which the engaging axle (147) enters are formed, and in an opposite side of which an one-step structure is formed such that another space for accepting the torsion spring (148) when a horizontal portion of the bottom bracket body (144a) covers a top portion of a bottom surface of the one-step structure. The bottom bracket (144) comprises a body portion (144a) integrated with a horizontal portion and a vertical portion extending perpendicularly from a perimeter of the horizontal portion, and an entering hole (144c) for inserting the engaging axle (147) and the bottom bracket axle (144b) for putting into the swing link groove (142d) are formed in the vertical portion.

In an assembled bendable apparatus (140) as illustrated in FIG. 5, the swing link (146) is disposed as to swing between the top bracket (142) and the bottom bracket (144), the swing link protrusion (146a) is exposed tilted in a bottom surface of the bendable apparatus (140), and both arms of the torsion spring (148) hits the sides of the top bracket (142) and the bottom bracket (144) respectively in a direction where the two brackets (142) are opened.

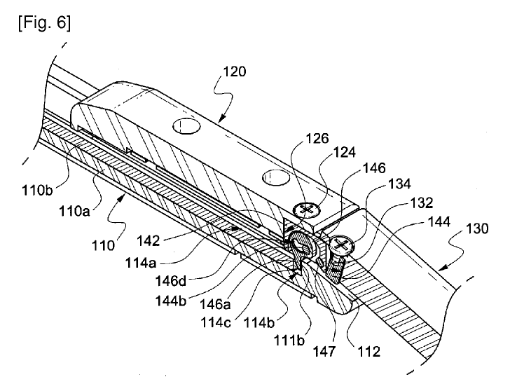

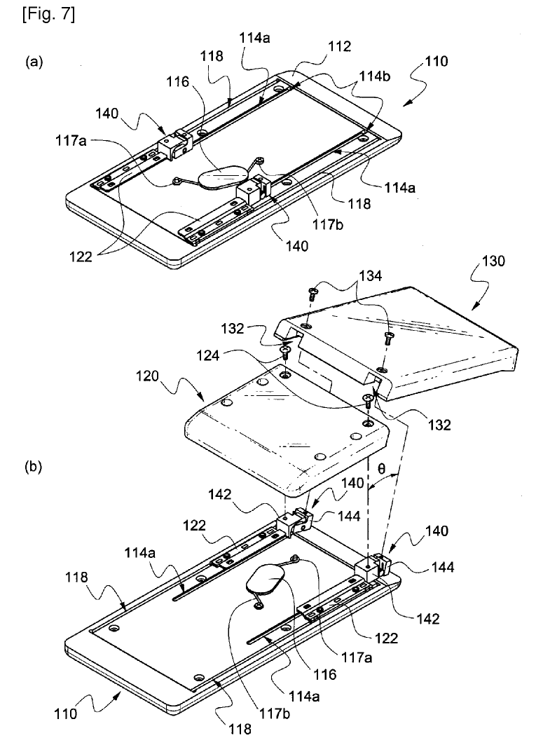

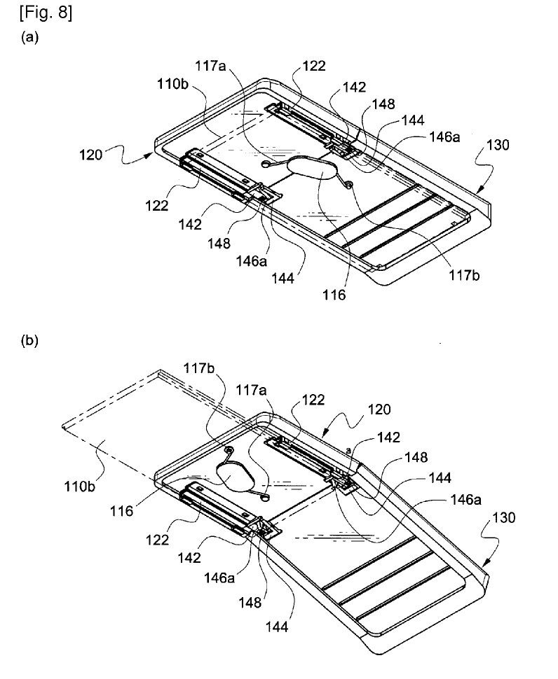

FIGS. 6 through 8 shows a bendable apparatus (140) installed on a cellular phone (100) in more detail. FIG. 6 shows a cross-sectional view along the line A-A in FIG. 1, which shows the assembled bendable apparatus in the bent state. Also, FIG. 7(a) shows a perspective view illustrating the bendable sliding type cellular phone (100) of FIG. 1, which is in the closed state with the top moving portion (120) and the bottom moving portion (130) removed, and FIG. 7(b) shows an exploded perspective view illustrating disassembled top and bottom moving portion (120, 130) in the opened state. FIG. 8(a) shows a perspective view illustrating of the bendable sliding type cellular phone (100) of FIG. 1 in the closed state with the base portion (110) removed, and FIG. 8(b) shows a perspective view illustrating the opened state with the bottom moving portion (130) bent. The top moving portion (120) is fixed to the slider (120) and the top bracket (142) of the bendable apparatus (140). Therefore, if the user applies an external force to push up or pull down any one of the two moving portions (120, 130), the slider (122), the bendable apparatus (140), the top moving portion (120), and the bottom moving portion (130) get together as one to perform a sliding motion. Also in the bendable apparatus (140), the bottom bracket (144) is bent (the bottom moving portion (130) is also bent) only when the swing link protrusion (146a) is pushed into the bending-catching groove (114b), and if an external force pushes up the top moving portion (120), the swing link protrusion (146a) gets out of the bending-catching groove (114b) and pushed back on the bottom surface of the shallow guide groove (114a) such that the entire swing link (146) rotates counterclockwise and thereby the bottom bracket (144) (along with the bottom moving portion (130)) recovers the straightened state from the bent state. For a reference, in such a sliding motion, the torsion spring (116) add some force to the sliding motion of the top moving portion (120) initiated by the external force. Therefore, the top moving portion (120) may be pushed up or pulled down all the way even if the user does not push up or pull down all the way.

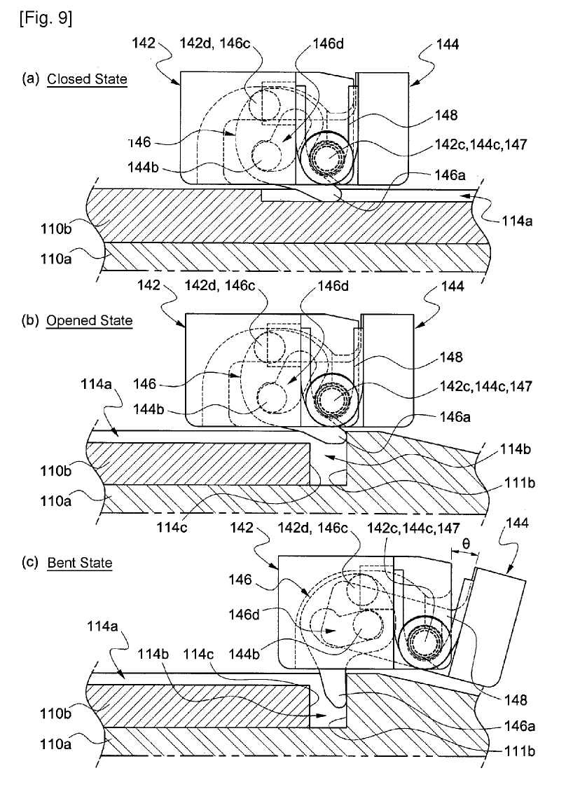

Bending and straightening of the bendable apparatus (140) is described in more detail referring to FIG. 9. FIG. 9(a)-(c) show cross-sectional views along the lines B-B, C-C, D-D in FIG. 1, illustrating the operation of the bendable apparatus (140) on the base portion (110) in the closed, opened, and bent states respectively.

First, in the closed state shown in FIG. 9(a), the bendable apparatus (140) is disposed at a topmost position of the guide groove (114a). Here, the swing link protrusion (146a) is supported by the bottom surface of the guide groove (114a), facing the 4 o'clock direction. And, the bottom bracket axle (144b) is disposed in a crooked groove provided in the bottom position of the swing link groove (142d). Under these conditions, a force by the torsion spring (148) pushing the top and bottom bracket (142, 144) in an opposite direction is applied, but the bottom bracket axle (144b) is latched at a step of a crooked groove of the swing link groove (146), standing the force. As a result, the swing link (146) does not rotate but holds in place, by which the bottom bracket (144) cannot rotate about the top bracket (142) and thus the two brackets (142, 144) of the bendable apparatus (140) is kept in the straightened state along a straight line. Furthermore, since the swing link protrusion (146a) is limited not to rotate clockwise by the bottom surface of the guide groove (114a), the straightened state is kept more stably. Therefore, in FIG. 9(a), the top moving portion (120) and the bottom moving portion (130) are in the close state with respect to the base portion (110), and the bottom moving portion (13) is kept in the straightened state with respect to the top moving portion (120).

The ‘opened state’ shown in FIG. 9(b) is a state right before the bendable apparatus (140) comes down to the bottommost position of the guide groove (114a) to go to the bent state. In a process changing from the ‘closed state’ to the ‘opened state’ the relative relations between the components of the bendable apparatus (100) are not changed and just move downward along the guide groove (114a) as one body, such that the two moving portion (120, 130) move to expose considerable portion but a part of top portion of the bottom moving portion (130).

In the ‘bent state’ shown in FIG. 9(c), the top bracket (142) moves further in a moving direction by the force which is applied in the moving direction (to the right in the figure) in the ‘opened state’ and the swing link protrusion (146a) cannot proceed any more in the moving direction since it hits the side wall (111b) of the body, and therefore the entire swing link (146) rotates clockwise about the swing link axle (146c) axle-joined with the top bracket (142). In this rotating of the swing link (146), the swing link groove (146d) rotates clockwise by some angle (θ), by which the bottom bracket axle (144b) gets out of the crooked groove of the swing link groove (146d) and moves to a top portion of the swing link groove (146d), and during this process the bottom bracket axle (144b) is pushed by the side wall of the swing link groove (146d) so as to be raised vertically upward. That is, since the bottom bracket axle (144b) is raised upward while the bottom bracket (144) is axle-joined with the top bracket (142) through the engaging axle (147), the horizontal portion of the bottom bracket (144) rotates clockwise about the engaging axle (147) by the principle of lever, such that the bottom bracket (144) is bent against the top bracket (142) by some angle (θ). The distance between the swing link axle (146c) and the bottom bracket axle (144b) is shorter in the bent state rather than in the closed state, and the bending angle is allowed by the difference in distances between the swing link axle (146c) and the bottom bracket axle (144b) in these two states. According to the bending of the bottom bracket (144), the bottom moving portion (130) engaged to the bottom bracket (144) is bent by the angle (θ). This bending is allowed due to the fact that the portion of the base portion (110) facing the bottom bracket (144) includes the tilted surface (112). Also, in the process of this transition to the ‘bent state’ the swing link protrusion (146a) is pushed further into the bending-catching groove (114a) so as to be put almost upright keeping hitting the side wall (111b) of the body. In this process, the torsion spring (148) provides a force which facilitates bending of the bottom bracket (144).

The transition between states is reversible. That is, the operation of all components during the transition from the bent state through the opened state to the closed state is same as a reversed operation. If an external force for pushing up is applied to either the top moving portion (120) or the bottom moving portion (130) in the bent state, the bendable apparatus (140) moves as one body, and in the process the swing link protrusion (146a) touches a side wall (114c), that is, a bottommost edge of the guide groove (114a), and the bendable apparatus (140) is pushed further upward, such that the swing link protrusion (146a), the swing link body (144b) rotate counterclockwise about the swing link axle (146a) and ride on the guide groove (114a), and the bottom bracket axle (144b) rides on the swing link groove (146d) which rotates counter-clockwise to come down, being received in the crooked groove and being caught therein. By this, the bottom bracket (144) rotates counterclockwise about the engaging axle (147) by the principle of lever, being engaged with the top bracket (142) again and aligned along a line. Thus, the top moving portion (120) and the bottom moving portion (130) go to a straightened state along a straight line, move upward due to the force kept being applied, and go to the closed state shown in FIG. 9(a).

The opening and closing operations (i.e., the operations of bending and closing) between the top bracket (142) and the bottom bracket (144) of the bendable apparatus (140) is performed by the swing link (146) working as a handle. In the ‘bent state’ shown in FIG. 9(c), even though a force is applied to the bottom bracket (144) upward, the bent state is kept as it was as long as the swing link does not rotate. When the bendable apparatus (140) is installed in a cellular phone (100), therefore, if a force is applied to the bottom moving portion (130) in a direction opposite to the arrow in FIG. 1(b), the bottom bracket axle (144b) transfers a force approximately perpendicularly to the side wall of the swing link groove (146d) by the principle of lever, but since it does not cause a rotation of the swing link (146), the bottom moving portion (130) is not straightened and kept so. The swing link (146) rotates only when a force is applied in a direction (pushing upward) opposite to the arrow in FIG. 1(a). A supporting axle of the handle, i.e., the swing link axle (146c) engaged to the top bracket (142) is presented only as an exemplary case, which can be changed to engaging the bottom bracket (144).

### Mode for the Invention

### (2) Second Embodiment

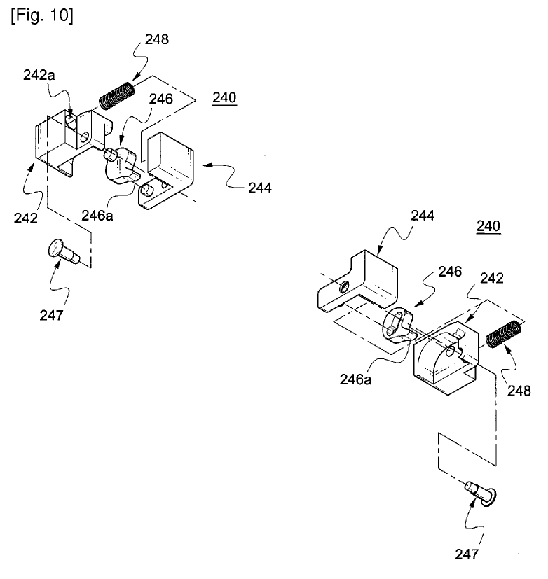

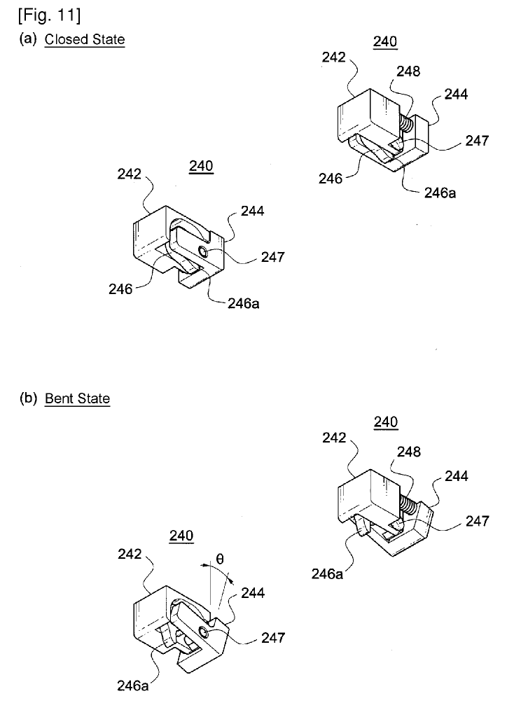

FIGS. 10 and 11 show a bendable apparatus (240) according to a second embodiment of the invention. The bendable apparatus (240) comprises a top bracket (242), a bottom bracket (244), a swing link (246), and an engaging axle (247), and the components are almost same as the corresponding components or their engaging relations of the bendable apparatus (140) according to the first embodiment of the invention. A difference lies in that a coil spring (248) is disposed between the top bracket (242) and the bottom bracket (244) instead of the torsion spring (148). Also, a spring groove (242a) is formed on the top bracket (242) for a stable receiving of the coil spring (248). The same is true with the bottom bracket (244) (not shown).

The operation of the assembled bendable apparatus (240) is almost same as that of the bendable apparatus (140) according to the first embodiment. That is, the swing link protrusion (246a) is slanted pointing to a 4 o'clock direction in a closed state, while pointing to a 6 o'clock direction in a bent state. To go from the closed state to the bent state, the top bracket (242) is fixed not to move and then a force for rotating the bottom bracket (244) clockwise must be applied. When the bendable apparatus (240) is installed on a cellular phone (100), the force is obtained from a force pulling down the top and bottom moving portion (120, 130) by the user as specified in the first embodiment. In the process, the coil spring (248) facilitates the top bracket (242) and the bottom bracket (244) to rotate about the engaging axle (247) by some angle (θ).

### (3) Third Embodiment

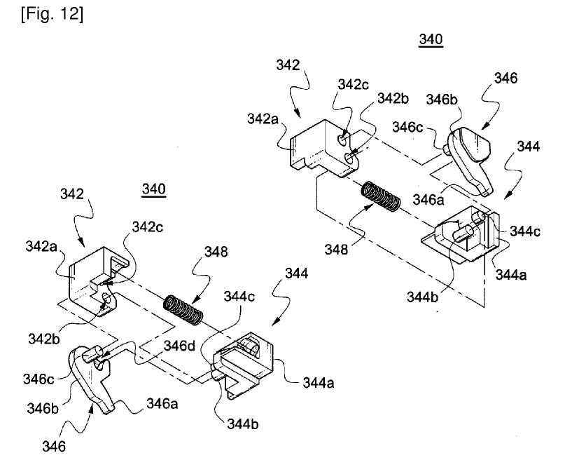

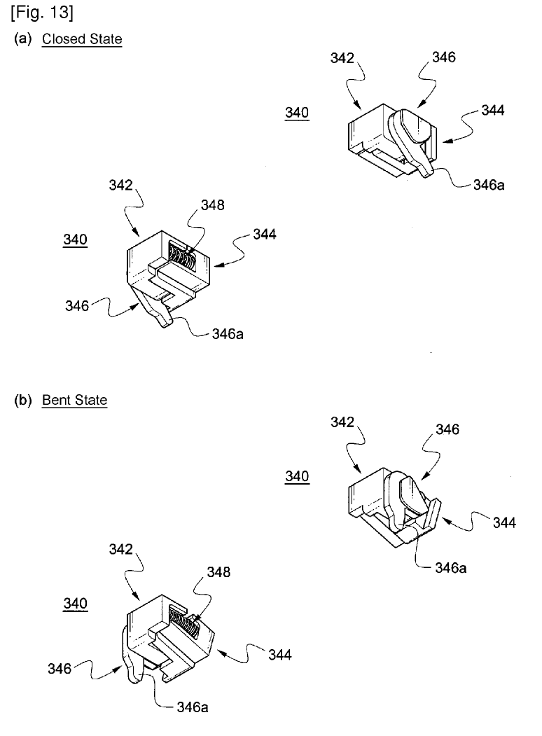

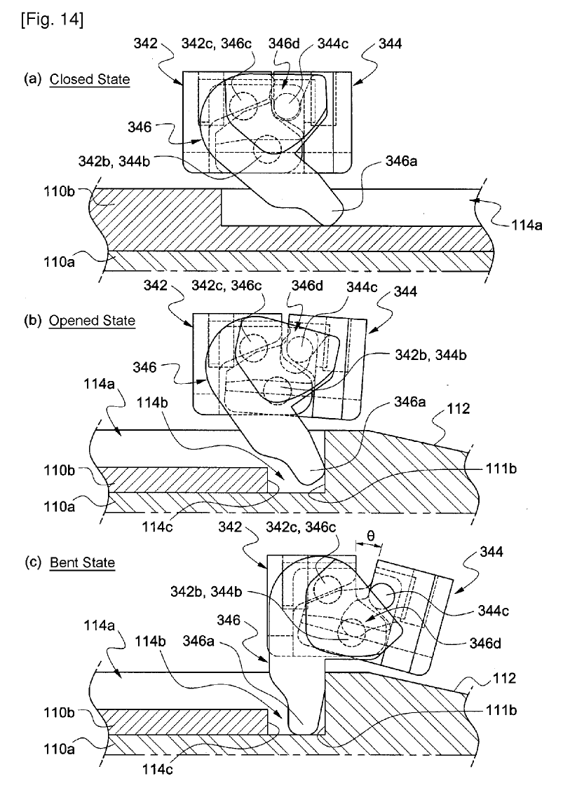

FIGS. 12 and 13 show an exploded perspective view and an assembled view of a bendable apparatus (340) according to a third embodiment of the invention respectively, and FIG. 14 shows an operation of state transition when the bendable apparatus (340) is installed on a cellular phone (100). The bendable apparatus (340) comprises a top bracket (342), a bottom bracket (344), and a swing link (346) as in the first embodiment. However, there is a difference from the first embodiment as follows. That is, i) the means for axle-joining the top bracket (342) and the bottom bracket (344) is not a separate engaging axle (147), but a fixed engaging axle (344b) integrated with the bottom bracket (344), ii) the swing link (346) engages not between the top bracket (342) and the bottom bracket (344), but an outside portion of the top bracket (342), iii) a coil spring (348) is employed as in the second embodiment.

More specifically, two entering holes (342b, 342c) are formed on an inner floor of a body (342a) of the top bracket (342). A swing link axle (346c) extends perpendicularly from a top portion of a side of a flat body (346a) of the swing link (346), nearby a swing link groove (346d) is formed by digging by some depth (a length corresponding to the bottom bracket (344)′ rotation by some angle θ) inward from a side surface of the body (346b), a swing link protrusion (346a) extends from a bottom portion the body (346b). The swing link groove (346d) gets narrower going from the opening to the inside, and the end portion has a slightly crooked shape going into the innermost position. In the bottom bracket (344), a first bottom bracket axle (344b) and a second bottom bracket axle (344c) extend perpendicularly respectively from a bottom end and a top end of inside of the body (344a). The top bracket (342) and the bottom bracket (344) may provide a space for receiving the coil spring (348) between them when assembled.

The top bracket (342) and the bottom bracket (344) are engaged by inserting the first bottom bracket axle (344b) into the entering hole (342b) of the top bracket (342), such that the bottom bracket (344) rotates about the axle. Also, the swing link axle (346c) is inserted into the entering hole (342c), such that the swing link (346) is able to rotate about the swing link axle (346c). Further, the second bottom bracket axle (344c) is disposed inside the swing link groove (346d). The coil spring (348) is enclosed inside inner wall between the top bracket (342) and the bottom bracket (344).

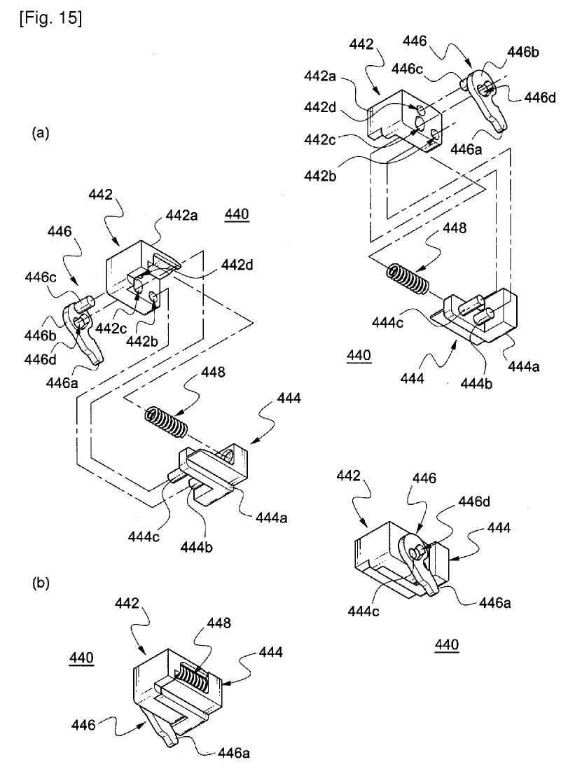

When the bendable apparatus (340) is installed on a cellular phone (100), the operation of state transition is described referring to FIG. 15. To simplify the figure, the expression of the coil spring (448) was omitted. In a closed state, since the second bottom bracket axle (344c) is located in an innermost position of the swing link groove (346d) and locked by the side wall of the swing link groove (346d) touching a right side surface of the swing link groove (346d), the force with which the coil spring (448) pushes the bottom bracket (344) is overcome. Also, an opening of the swing link groove (346d) opens upward, and the swing link protrusion (346a) is supported by the guide groove (114d) and points to approximately 4 o'clock direction. Under this condition, the bendable apparatus (340) goes down to the end of the guide groove (114a) due to an external force for pulling down, and when the swing link protrusion (346a) hits the side wall (111b) of the body (this is the opened state shown in FIG. 14(b)) the swing link (346) rotates clockwise about the swing link groove (346c) from then on, and in this process the second bottom bracket axle (344c) which was locked by an opening step of the crooked groove in the innermost position of the swing link groove (346d) gets out of the opening step toward the opening. The swing link protrusion (346a) enters deeply into the bending-catching groove and the swing link (346) rotates until the swing link protrusion (346a) stands upright in a 6 o'clock direction. In the process, the bottom bracket (344) is pushed by an opening of the swing link groove (346d) and rotates clockwise about the first bottom bracket axle (344b) axle-joined to the top bracket (342). If the bottom bracket (344) rotates by some angle (θ), the inside surface hits the inside surface of the top bracket (342) so as to be unable to rotate any more, going into a bent state (FIG. 14(c)). Thereby, the top moving portion (120) and the bottom moving portion (130) fixed to the top side of the top bracket (342) and the bottom bracket (344) respectively go into the bent state. Since in the bent state the second bottom bracket axle (344c) is locked while riding on a left protrusion of an opening of the swing link groove (346d), the bottom bracket (344) keeps the bent state without a gap as long as the swing link (346) does not rotates counterclockwise. The operation for going from the bent state through the opened state to the closed state is same as the operation in the above in a reverse order.

### (4) Fourth Embodiment

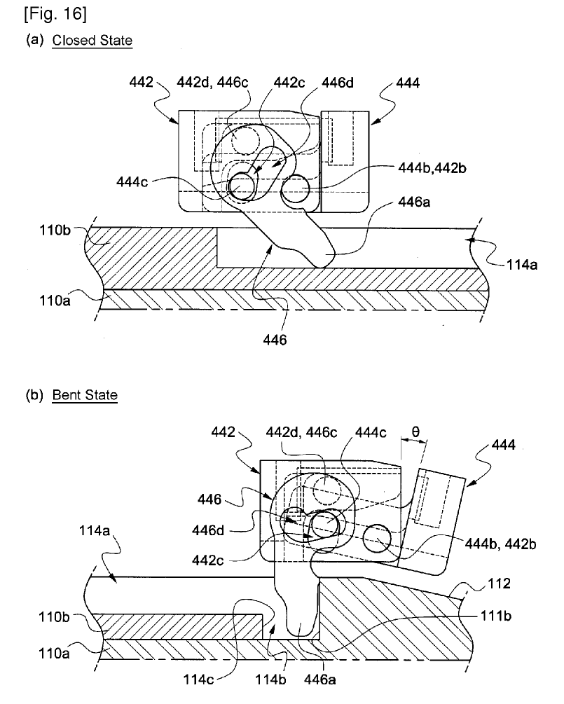

FIG. 15 shows an exploded perspective view and an assembled view of a bendable apparatus (440) according to a fourth embodiment of the invention, and FIG. 16 shows operations for each state when the bendable apparatus (440) is installed on a cellular phone (100). A swing link protrusion (446a) extends outward from a side surface of a body (446b) of the swing link (446) such that it looks like a small lock, and the swing link axle (446c) is disposed at a farthest perimeter from the swing link protrusion (446a) similarly to the previous embodiments. Also, the swing link groove (446d) extends in a direction of length as the swing link groove (146d) in the first embodiment and has an end portion having a crooked shape. However, considering that the swing link groove (446d) is formed on the same surface as the swing link axle (446c), it is different from the first embodiment, but similar to the third embodiment. The body (442a) of the top bracket (442) includes a base surface and a vertical surface extending from two side perimeters of the base surface, and three through holes (442b, 442c, 442d) are formed on the base surface. The swing link (446) is engaged such that the swing link axle (446c) is inserted into the third through hole (442d) from an outside of the top bracket (442) and swing link (446) is able to rotate about swing link axle (446c). In a bottom bracket (444), the body (444a) comprises a base surface and a vertical surface standing upright around a mid-point of the base surface, and in the vertical surface the two axles (444b, 444c) extend vertically from the vertical surface. The first bottom bracket axle (444b) is inserted into the first through-hole (442b) of the top bracket (442) such that the bottom bracket (444) is engaged rotatably with the top bracket (442), and the second bottom bracket axle (444c) is inserted into the swing link groove (446d) through an elliptical second through-hole (442c) of the top bracket (442). Also, the spring (448) is disposed between the top bracket (442) and the bottom bracket (444), and applies a force to open the two brackets (442, 444).

In a closed state of a bendable sliding type cellular phone (100) installed with the bendable apparatus (440), as shown in FIG. 16(a), the swing link protrusion (446a) disposed in the guide groove (114a) is tilted approximately in a 4 o'clock direction, and the second bottom bracket axle (444c) is disposed at a bottommost position of the second through-hole (442c) of the top bracket (442), and at the same time at a bottommost position of the crooked portion. In this state, the second bottom bracket axle (444c) is held and locked at an opening step of the crooked groove of the swing link groove (446d), locking the bottom bracket (444) so as not to rotate. If the top moving portion (120) and/or bottom moving portion (130) is pulled down by applying an external force in this situation, the bendable apparatus (440) goes through the opened state, and then to the bent state as shown in FIG. 16(b). In the transition of states under the force, the swing link protrusion (446a) hits the side wall (111b) of the body to rotate the swing link (446) clockwise about the swing link axle (446c), thereby the swing link groove (446d) rotates clockwise and the second bottom bracket axle (444c) gets out from the locking, escapes from the curved bottom side of the swing link groove (446d) and moves upward, and at the same time moves upward from the bottom side to the top side of the second through-hole (442c) of the top bracket (442). The moving distance may be designed to be limited by a length of the second through-hole (442c) or a length of the swing link groove (446d). As a result of the operation, the second bottom bracket axle (444c) is raised vertically a little, and due to this raising the bottom bracket (444) rotates clockwise by some angle (θ) about the first bottom bracket axle (444b). Under this rotation, the second bottom bracket axle (444c) is locked by a top inside wall of the second through-hole (442c) and cannot rotate any more. The second bottom bracket axle (444c) is also locked by a side wall of the swing link (446) supporting itself, and returning to an original state of the bottom bracket (444) becomes impossible as long as the swing link (446) does not rotate counter-clockwise. Through these serial processes, the bottom bracket (444) and the bottom moving portion (130) are bent about the top bracket (442) and the top moving portion (120) by some angle (θ). These transitions between the states are reversible.

### (5) Fifth Embodiment

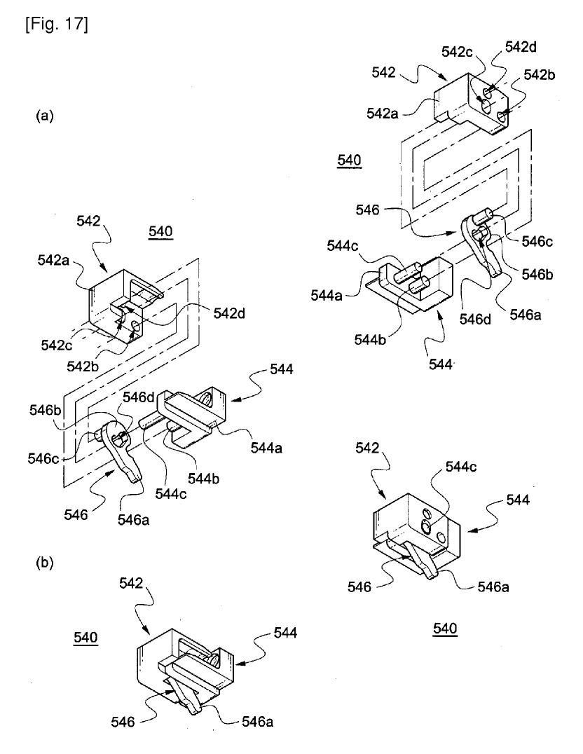

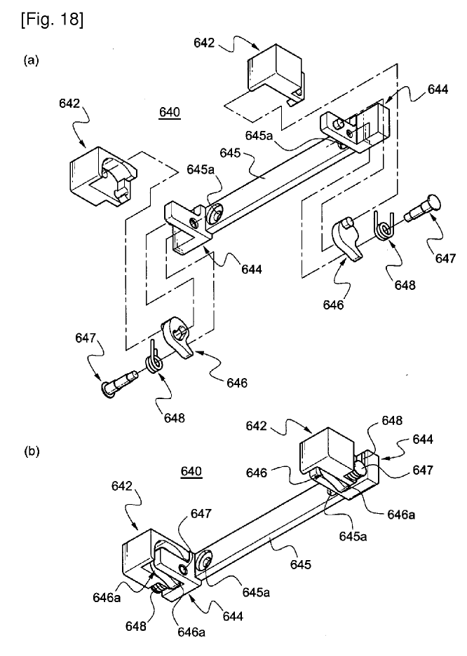

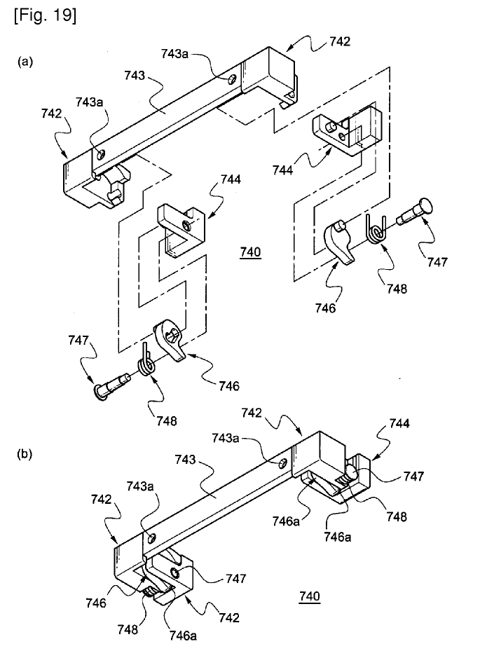

A bendable apparatus (540) according to a fifth embodiment of the invention as shown in FIG. 17 is very similar to the bendable apparatus (440) of the fourth embodiment in many aspects. The structures of a top bracket (542) including a body (542a) and three through-holes (542b, 542c, 542d) formed thereon and a bottom bracket (544) including a body (544a) and two axles (544b, 544c) are almost the same as in the fourth embodiment. A swing link (546) including a swing link protrusion (546a), a swing link hole (546b), and a swing link axle (546c) and the shapes of each component are same as the swing link (446) of the fourth embodiment. However, the direction of the swing link (546) standing upright is different by 180 degrees from that of the swing link (446) of the fourth embodiment. This is due to the fact that the swing link (546) is disposed between the top bracket (542) and the bottom bracket (544) and the swing link axle (546c) is inserted into the third through-hole (542d) facing outward from the inside of the top bracket (542). The first bottom bracket axle (544) is inserted into the first through-hole (542b) and the bottom bracket (544) is axle-joined to the top bracket (542), and the second bottom bracket axle (544c) is inserted into the second through-hole (542c) of the top bracket (542) through the swing link hole (546d). By these engagements, the swing link (546) is rotatably engaged between the two brackets (542, 544), and by the rotating motion of the swing link (546), the bottom bracket (544) can be bent by some angle about the top bracket (542) or straightened along a line.

### (6) Sixth Embodiment

A bendable apparatus (640) according to a sixth embodiment of the invention comprises a top bracket (642), a bottom bracket (644), a swing link (646), an engaging axle (647), and a spring (648) and each of the components are engaged with corresponding components in the same way as the a bendable apparatus (140). A difference is that, in order to facilitate installing on a cellular phone (100), two bottom brackets (644) are connected with a link member (645) in advance and integrated into one. Since the two bendable apparatus (640) are integrated into one with the link member (645), installing on the cellular phone becomes convenient. There are provided a hole (645a) for connecting to the bottom moving portion (130) on both sides of the link member (645). The operations of being and straightening of the bendable apparatus (640) through a rotating motion of the swing link protrusion (646a) are same as in the first embodiment.

### (7) Seventh Embodiment

A bendable apparatus (740) according to a seventh embodiment of the invention shown in FIG. 19 comprises a top bracket (742), a bottom bracket (744), a swing link (746), an engaging axle (747), and a torsion spring (748), which have the same structure and engaging relations as in the sixth embodiment, but the two top bracket (742) are integrated into one with the link member (743), not like in the sixth embodiment, in which the bottom bracket (644) is connected to the link member (645). There are provided hole (743a) for connecting to the top moving portion (120) with screws on both sides of the link member (743). The operations of being and straightening of the bendable apparatus (740) through a rotating motion of the swing link protrusion (746a) are same as in the first embodiment

### (8) Eighth Embodiment

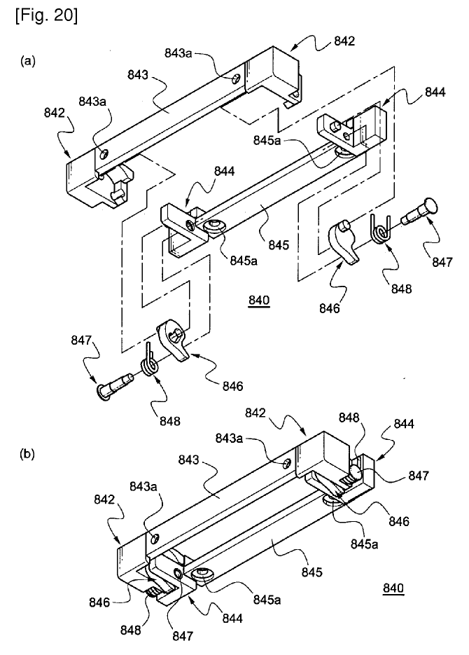

A bendable apparatus (840) according to an eighth embodiment of the invention shown in FIG. 20 is given by combining the sixth embodiment and the seventh embodiment, comprising a top bracket (742), a bottom bracket (744), a swing link (746), an engaging axle (747), and a torsion spring (748) that have the same structure and engaging relations as in the sixth embodiment, and the two top brackets (842) are connected to each other into one with a first link member (843), and the two bottom brackets (844) are connected to each other with a second link member (845). The bendable apparatus (840) may be installed to a cellular phone (100) with screws through holes (843a, 845a) provided in the first and second link member (843, 845).

### (9) Ninth Embodiment

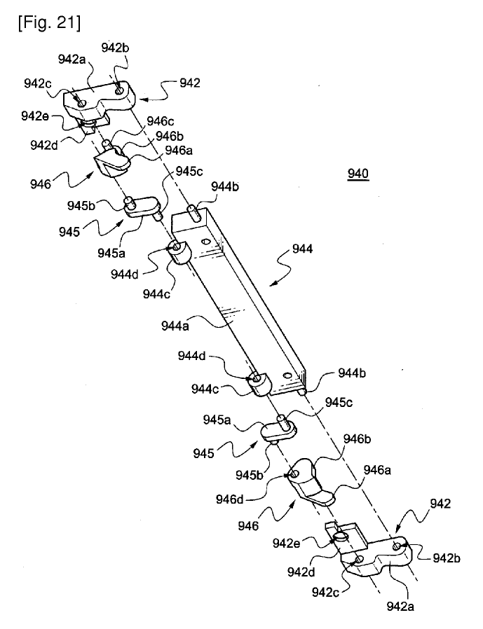

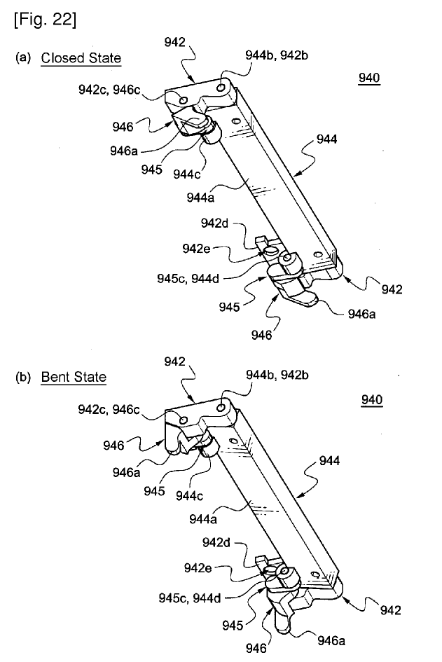

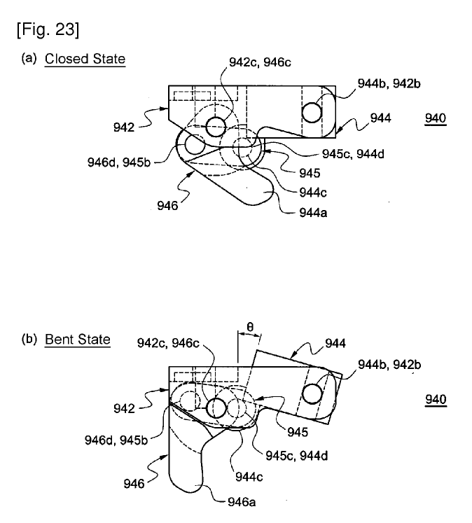

A bendable apparatus (940) according to a ninth embodiment of the invention is shown in FIGS. 21-23. Referring to the exploded perspective view of FIG. 21, the bendable apparatus (940) comprises two top brackets (942), two bottom bracket (944) integrated into one, two links (945), and two swing links (946). In the top bracket (942), the top surface of the body (942a) is flat, the bottom surface is formed by two connected mountains, the first and second through-holes (942b, 942c) are formed approximately in the middle of the two mountains, a vertical portion (942d) having top surfaces of two steps standing upright at a perimeter near to the second through-hole (942c) of the body, and a through-hole (942e) is formed at a top portion thereof. The swing link (946) comprises a body (946b) having a constant thickness and an asymmetrically round bottom surface and a swing link protrusion (946a) extending from a perimeter end of one side of the body (946b) in a direction opposite from the body (946b) and having a round end, and the body (946b) and the swing link protrusion (946a) form a step surface. Also, the spring link axle (946c) extends perpendicularly toward the top bracket (942) on a surface to which the swing link protrusion (946a) of the body (946b) is connected, and a through-hole (946d) is formed on the opposite side of the body (946b). The link (945) comprises a body (945a) having two round ends and first and second link axles (945b, 945c) extending perpendicularly from end portions opposite to both sides of the body (945a). In the bottom bracket (944), an engaging axle (944b) extends in a direction of length from both sides of the body (944a) having a shape of rectangular bar, a fixing protrusion (944c) is fixed around an edge where a bottom surface meets other side surface of the body (944a), and a through-hole (944d) is formed in the fixing protrusion (948c). The illustrated bottom bracket (948) may be considered as two bottom brackets connected into one body with the body (944a). The swing link axle (946c) is inserted into the second through-hole (942c) inside the top bracket (942) and engaged to enable axial rotation. The first link axle (945b) of the swing link (946) is inserted into the through-hole (946d) of the body (946b), and the second link axle (945c) is inserted into the through-hole (944d) inside the fixing protrusion (944c) of the bottom bracket (944). When the assembled bendable apparatus (940) is installed on a cellular phone (100), the top bracket (942) and the bottom bracket (944) are fixed to the top moving portion (120) and the bottom moving portion (130) respectively.

FIG. 22(a), (b) show a closed state and a opened state of the assemble bendable apparatus (940), and FIG. 23(a), (b) show cross-sectional views for describing the transition between the closed state and the opened state. Referring to the figures, the operation of the state transition of the bendable apparatus (940) will be described. In the closed state, the link axle (945b) and the second link axle (945c) are located at approximately same level, the swing link axle (946c) axle-joined to the top bracket (942) is located at a much higher level, the three axles forming slightly tilted triangle. In this state, if a clockwise rotating force is applied to the swing link protrusion (946a) (the rotating force is applied when the swing link protrusion (946a) hits the side wall (111b) of the body and a force pulling down is kept at the top and bottom moving portions (120, 130), the swing link (946) rotates clockwise about the spring link axle (946c), and accordingly the first link axle (945b) engaged to the through-hole (946d) of the body (946b) rotates clockwise about the swing link axle (946c). As a result, as the level of the first link axle (945b) is raised, the link (945) is also raised along approximately in a 10 o'clock direction as a whole, and the related force is transferred to the bottom bracket (944). As a result, the fixing protrusion (944c) of the bottom bracket (944) engaged to the second link axle (945c) is raised, and then the bottom bracket (944) rotates by some angle (θ) about the engaging axle (944b). In such a bent state, the spring link axle (946c) is lowered to almost a same level as the two link axles (945b, 945c), and the angle between the link (945) and a side surface of the bottom bracket (944) gets larger than that in the closed state. On the contrary, if a counter-clockwise rotating force is applied to the swing link protrusion (946a), the state goes back to the closed state.

### (10) Tenth Embodiment

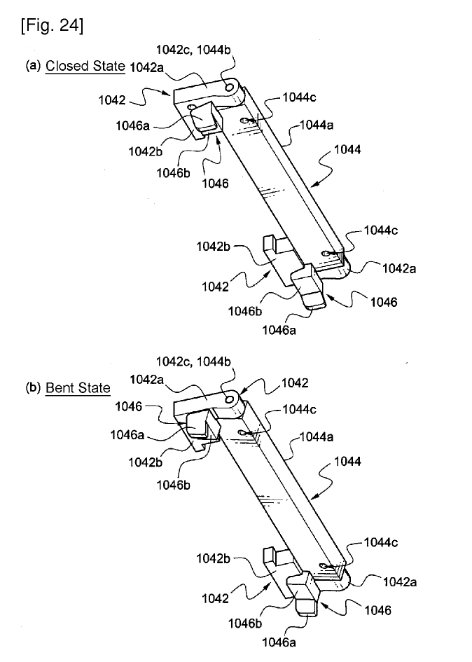

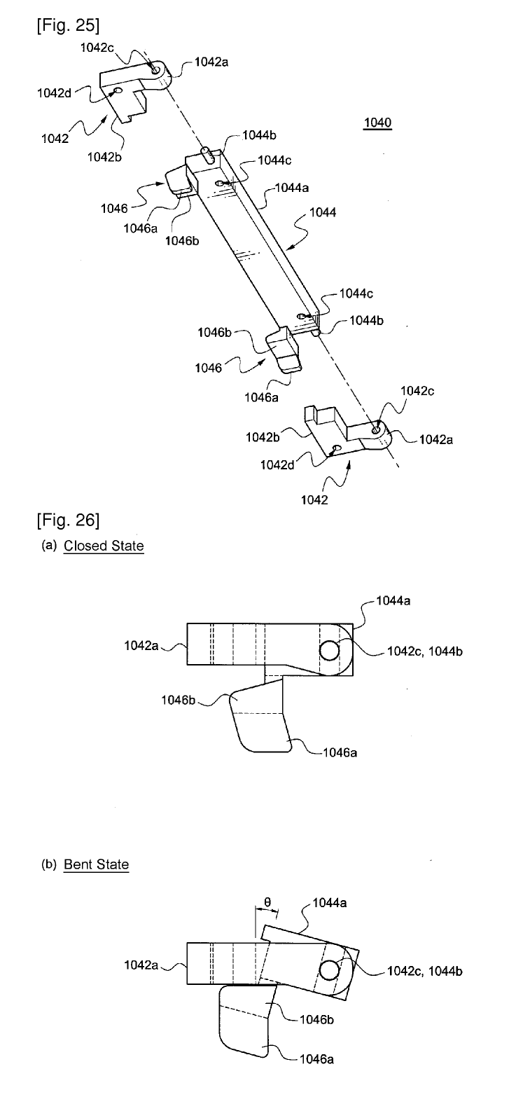

FIGS. 24-26 show a bendable apparatus (1040) according to a tenth embodiment of the invention. Referring to an exploded perspective view of the bendable apparatus (1040) shown in FIG. 24, the bendable apparatus (1040) comprises two top brackets (1042), two bottom brackets (1044) integrated into one, and two swing protrusion (1046).

In the bottom bracket (1044), an engaging axle (1044b) extends upright outward from both side surfaces of a body (1046a) having a long rectangular bar shape, and vertical through-hole (1044c) are formed around end portion on both sides. In the swing protrusion (1046), a supporting portion (1046b) is fixed around an edge of the ending portions on both side of the body (1044a) of the bottom bracket (1044), and a protrusion (1046a) standing upright downward from outside edge of the supporting portion (1046b). The top surface of the supporting portion (1046b) is tilted from the bottom surface of the body (1044a) and the bottom surface of the body (1042a) by some angle (θ).

The body of the top bracket (1042) comprises a joint body (1042a) that faces a side surface of the body (1044a) of the bottom bracket (1044) and axle-joined with the engaging axle (1044b) through a through-hole (1042c) and a rotating-limiting portion (1042b) that faces a tilted top surface of the supporting portion (1046b) of the bottom bracket with some angle (θ) and limits the rotating angle of the bottom bracket (1044). The top bracket (1042) has a lateral shape of a chair, the back of which corresponds to the body (1042a), and the seat and the foot rest of which correspond to the rotating-limiting portion (1042b). The rotating-limiting portion (1042b) is provided with the through-hole (1042d) for engaging with screws.

Two such top brackets (1042) are inserted into the engaging axle (1044b) on both sides of the bottom bracket (1044), and thereby the bottom bracket (1044) engages so as to rotate about the bottom bracket (1044). The top bracket (1042) and the bottom bracket (1044) engage the top moving portion (120) and the bottom moving portion (130) of the cellular phone (100) through the second through-hole (1042d) and the through-hole (1044c) respectively.

FIGS. 25(a) and (b) show a closed state and an opened state of an assembled bendable apparatus (1040) respectively, and FIGS. 26(a) and (b) show cross-sectional view of a closed state and a bent state. To describe the operation of state transition of the bendable apparatus (1040) referring to the figures, since the bottom bracket (1044) is axle-joined simply with the top bracket (1042), if the swing link protrusion (1046a) is pushed from the right side to the left side in the closed state as shown in FIG. 26(a), the bottom bracket (1044) starts to rotate clockwise about the engaging axle (1044b) and keeps rotating until the top surface of the supporting portion (1046b) touches the bottom surface of the top bracket (1042). By this rotation, the body (1044a) rotates by some angle (θ). If an external force is applied to the swing link protrusion (1046a) in a reverse direction, the body (1044a) rotates in the reverse direction, returning to the closed state.

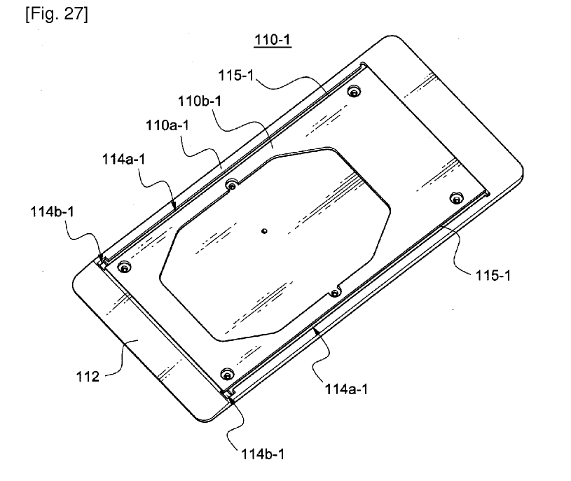

On the other hand, the base portion (110) of the cellular phone (100) shown in FIGS. 1-3 is provided with a road (a guide rail (115)) for the top and bottom moving portions (120, 130) to move along and a road (a guide groove (114a)) for the bendable apparatus (140) to move along. However, there is no need to provide separate roads, but one common road can be provided. The base portion (110-1) in FIG. 27 is another embodiment of the base portion (110) in FIG. 1, and the base portion (110-1) provides a common guide groove (114a-1) instead a road for the top and bottom moving portions (120, 130) to move and a road for the bendable apparatus (140) to move. That is, the base portion (110-1) has a structure, in which if the guide plate (110b-1) is received in a sink of the body (110a-1) and engaged, a guide groove (114a-1) is formed by a gap between right and left side wall of the body (110a-1) and a side surface of the guide plate (110b-1). The other features are almost same as in the first embodiment. That is, in order to guide a sliding motion of the top and bottom moving portions (120, 130), a guide rail (115-1) is formed by forming steps along right and left side surfaces of the guide plate (110b-1). A deeper bending-catching groove (114b-1) is provided in an end portion of the bottom side of the guide groove (114a-1). The bendable apparatus (140) and the slider (122) are disposed touched in a line, and the bendable apparatus (140) is located toward the bending-catching groove (114b-1).

### Modified Embodiment

In the above, embodiments, in which a bendable apparatus assembled as a separate item is installed on a cellular phone (100), have been described, but it is possible to realize a bendable apparatus (140, 240, . . . , 1040) integrated into one body with the cellular phone. For example, in designing the top moving portion (120) and the bottom moving portion (130) of the cellular phone (100), the top bracket and the bottom bracket of each of the bendable apparatus (140, 240, . . . , 1040) are designed as a part of them. According to such a design, only the swing link (146, 246, . . . ) need to be assembled to the top moving portion and/or the bottom moving portion.

Also, the bendable apparatus (140, 240, . . . , 1040) may be applied to other kinds of devices that open and close in the sliding type besides the cellular phone. The bendable apparatus (140, 240, . . . , 1040) according to the present invention can be applied to any device that includes a keyboard and a screen disposed on a substrate portion and a sliding portion adopting a sliding type open-and-close structure. For example, the present invention can be applied to a PDA, a smart phone, a small-sized notebook computer adopting a sliding type open-and-close structure.

The ninth and the tenth embodiments can be modified as follows. That is, they can use separate independent bottom bracket structures instead the bar-shaped body (944a or 1044a) for connecting the two bottom brackets into one.

### INDUSTRIAL APPLICABILITY

The above embodiments are some embodiments out of many enabled embodiments just for helping the community of the art to understand the invention, but do not limit the scope of the invention. Therefore, the other equivalent embodiments may include various possible changes that are included in the inventive points of the invention.

The present invention is applicable to various electronic devices of a bendable sliding apparatus that can be applied to mobile devices including a cellular phone, a PDA, and a mobile PC, in which a moving member that is slidably combined to a base member may be bent by a predetermined angle when opened.

1. A bendable apparatus comprising:
a top bracket;
a bottom bracket which is rotatably axle-joined with the top bracket; and
a swing link which is rotatably axle-joined to the top bracket, concurrently engages with a portion of the bottom bracket,
a swing link which is rotatably axle-joined to the top bracket, concurrently engages with a portion of the bottom bracket, and makes the bottom bracket rotate about the top bracket by an external force applied to a swing link protrusion and by a predetermined angle about an axle with which the bottom bracket is joined with the top bracket being rotated itself about the top bracket by an external force applied to a swing link protrusion, and makes the bottom bracket rotate by a predetermined angle about an axle which is joined with the top bracket.

2. The bendable apparatus of claim 1, further comprising a spring member disposed between the top bracket and the bottom bracket, wherein the spring member applies a pushing force to the two brackets in an opposite direction.

3. The bendable apparatus of claim 1, further comprising an engaging axle inserted into through-holes provided in the two brackets to axle-join the bottom bracket with the top bracket.

4. The bendable apparatus of claim 1, wherein an entering hole is formed in one of the top bracket and the bottom bracket, wherein an axle is formed in the other of the top bracket and the bottom bracket at a position corresponding to the entering hole, and wherein the top bracket is axle-joined with the bottom bracket by the axle's inserting into the entering hole.

5. The bendable apparatus of claim 1, wherein the swing link engages the bottom bracket by the axle of the bottom bracket inserting into a swing link groove formed in a body of the swing link, wherein the axle of the bottom bracket is forcibly guided to the swing link groove rotating with the body of the swing link and then the bottom bracket rotates by the predetermined angle.

6. The bendable apparatus of claim 1, wherein the rotating angle of the bottom bracket is limited by a length of the swing link groove or a structure, in which when the bottom bracket rotates by a predetermined angle, the bottom bracket touchesis blocked by a part of the top bracket and cannot rotate any further.

7. The bendable apparatus of claim 1, wherein the bendable apparatus keeps either a closed state in which the bottom bracket is aligned with the top bracket in a straight line without a gap, or a bent state in which the bottom bracket is opened against the top bracket by the predetermined angle, according to the rotationing angle of the swing link, and wherein the closed state and the bent state are turned into each other in either direction.

8. The bendable apparatus of claim 7, wherein as long as the swing link does not rotate in the closed state and the bent state, the bottom bracket is not able to rotate, being left in a gapless state.

9. The bendable apparatus of claim 1, wherein two bendable apparatuses are combined into a structure using a link member having a shape of a bar.

10. The bendable apparatus of claim 9, wherein the link member comprises either a first link member for connecting first and second top brackets of the two bendable apparatuses, or a second link member for connecting first and second bottom brackets of the two bendable apparatuses.

11. The bendable apparatus of claim 1, wherein an external force is applied to the swing link through a protrusion extended and exposed externally from a side of the body to an outside of the top bracket and the bottom bracket.

12. The bendable apparatus of claim 1, wherein each of the top bracket and the bottom bracket is provided with a fastening-hole for connecting with other objects through screws.

13. A bendable apparatus, comprising:
a top bracket;
a bottom bracket which is rotatably axle-joined with the top bracket;
a swing link which is rotatably axle-joined to the top bracket and includes a swing link protrusion exposed externally; and
a link which is disposed between the bottom bracket and the swing link and is rotatably axle-joined to the bottom bracket and the swing link at both ends, wherein the swing link rotates about the top bracket by the external force applied to itself through the swing link protrusion and pulling up the link, and wherein the bottom bracket is led by the link to rotate about the top bracket by a predetermined angle.

14. The bendable apparatus of claim 13, wherein the bendable apparatus comprises a pair of each of the top brackets, the bottom brackets, the swing links, and the links, and wherein the pair of bottom brackets are connected to each other into one body through a bar-shaped link member, which results in a structure that and each of the bendable apparatuses is provided at both ends of the link member.

15. The bendable apparatus of claim 13, wherein the swing link in the bendable apparatus comprises a protrusion extended from a side of the body of the swing link externally to the top bracket and the bottom bracket for receiving the external force.

16. A bendable apparatus, comprising:
a bottom bracket portion comprising a bar-shaped body, an engaging axle extended at both sides of the bar-shaped body and a pair of bottom brackets fixed integrally in a vicinity of each of both left and right edges of the body, wherein each of the bottom brackets including a base portion, fixed to the body, having a top surface fixed to the body and tilted with an angle to the bottom surface of the body and a protrusion portion erected perpendicularly downward from an outer edge of the base portion; and
a top bracket portion comprising a pair of top brackets, each of which being rotatably engaged to the engaging axle in both side of the body, wherein the top bracket comprises an engaging portion which faces a side of the body and axle joined to the engaging axle and a rotation-limiting portion which faces the top surface of the base portion of the bottom bracket with an angle and limits the rotating angle of the bottom bracket,
wherein the bottom bracket rotates by a predetermined angle about the top bracket when an external force is applied to the protrusion portion.

17. A bendable sliding opening type devices, comprising:
bendable apparatus according to claim 1;
a base portion provided with a guide groove extending in a direction of length thereof, a bending-catching groove having a depth deeper than the guide groove provided at an end of bottom of the guide groove, and a bottom portion includes a tilted surface; and
top and bottom moving portions fixed respectively to the top bracket and the bottom bracket and moving integrally,
wherein the moving portion faces and engages the base portion so as to allow a sliding motion, wherein the bottom moving portion is straightened in a straight line against the top moving portion so as to keep a closed state (straightened state) when the swing link protrusion of the bendable apparatus is in the guide groove, wherein after the bendable apparatus slides and moves downward under an external force pulling down the moving portion and then the swing link protrusion enters into the bending-catching groove it get caught therein and proceed no more and the swing link rotates in a first direction such that the bottom bracket is forced to rotate toward the tilted surface against the top bracket by an angle, and thereby the bottom moving portion moving together with the bottom bracket goes over to a bent state.

18. The bendable sliding opening type devices of claim 17, wherein in a process that the swing link protrusion escapes the bending-catching groove with an external force which pushes upward and gets on the guide groove, the swing link is forced to rotate by an angle in a direction opposite to the first direction by the applied force, and thereby the bottom moving portion moving together with the bottom bracket goes back to the closed state (straightened state).

19. The bendable sliding opening type devices of claim 17, wherein a guide rail which runs along the guide groove is provided on both sides of the base portion and fixed on sliders fixed on both sides of the bottom surface of the top moving portion, and wherein the sliders are slidably engaged to the guide rails.

20. The bendable sliding opening type devices of claim 17, further comprising a torsion spring for providing a force to pull down or push up to the ends, in which one arm is engaged to the bottom surface of the top moving portion and other arm is engaged to the top surface of the base portion, when the moving portion performs a sliding motion upward or downward.

21. The bendable sliding opening type devices of claim 17, wherein the guide groove and the bending-catching groove are provided so as to run together with side edges on both sides of the base portion.

22. The bendable sliding opening type devices of claim 17, wherein the top bracket and the bottom bracket are configured to be integrated with the top moving portion and the bottom moving portion respectively such that the swing link only is assembled with the top bracket and the bottom bracket.

23. The bendable sliding opening type devices of claim 17, wherein the bendable sliding opening type devices comprise a cellular phone, a PDA, a smart phone, and a notebook computer.

24. The bendable apparatus of claim 5, wherein the rotating angle of the bottom bracket is limited by a length of the swing link groove or a structure, in which when the bottom bracket rotates by a predetermined angle, the bottom bracket touchesis blocked by a part of the top bracket and cannot rotate any further.

25. The bendable apparatus of claim 14, wherein the swing link in the bendable apparatus comprises a protrusion extended from a side of the body of the swing link externally to the top bracket and the bottom bracket for receiving the external force.
